(19) United States
(12) Patent Application Publication
(10) Pub. No.: US 2014/0211432 A1
(43) Pub. Date: Jul. 31, 2014

(54) MULTIPURPOSE FASTENER FOR ELECTRONIC DEVICES

(71) Applicant: APPLE INC., Cupertino, CA (US)

(72) Inventors: Cesar LOZANO, Santa Clara, CA (US); Dominic E. Dolci, Berkeley, CA (US); Chiew-Siang Goh, San Jose, CA (US)

(73) Assignee: Apple Inc., Cupertino, CA (US)

(21) Appl. No.: 13/754,567

(22) Filed: Jan. 30, 2013

(51) Int. Cl. H05K 7/14

(52) U.S. Cl. CPC H05K 7/1417
USPC 361/759

(57) ABSTRACT

This application relates generally to a multipurpose fastener for an electronic device. More specifically, the multipurpose fastener is configured to both mechanically restrain at least one circuit board within a housing of an electronic device and to electrically couple at least one circuit board to the housing. In some embodiments, the fastener is configured to constrain two printed circuit boards such that they are disposed substantially parallel to one another. A conductive sleeve can be utilized to establish a predefined distance between the two circuit boards and to provide a conduit through which power can be transferred.

### BACKGROUND

1. Technical Field

The described embodiments relate generally to a multipurpose fastener. More specifically, a fastener configured to both mechanically and electrically couple two circuit boards together is disclosed.

2. Related Art

As electronic devices become increasingly smaller, the electronic component density associated with those devices has commensurably increased due in part to reduced size of printed circuit boards. In an effort to increase available board space, some electronic device designs include at least two separate circuit boards. Coupling the two separate circuit boards together can involve time-consuming and/or costly attachment processes. To make matters worse, electrical attachments for inter-board communication and/or power transfer can take up valuable circuit board real estate that can be better used for circuit routing, additional electrical components, or ultimately making the product smaller. Unfortunately, small connectors of the type that can feasibly fit in constrained spaces tend to be somewhat unreliable, requiring a backup connector that can take up even more space on each of the printed circuit boards.

Therefore, what is desired is an efficient and reliable way to secure internal components within a constrained volume of space.

### SUMMARY

This paper describes various embodiments that relate to mechanically and electrically coupling printed circuit boards.

In a first embodiment, a multipurpose fastener is disclosed. The multipurpose fastener can be used to assemble an electronic device including a housing and at least a first printed circuit board (PCB). The first PCB includes electrically conductive traces and a number of electronic components electrically interconnected by way of the electrically conductive traces. The multipurpose fastener includes at least a body portion. The body portion includes at least the following: a mechanical securing feature configured to mechanically secure the first PCB, and an electrical connection feature configured to electrically connect to at least one of the electrically conductive traces of the first PCB.

In another embodiment, a multipurpose fastener is disclosed. The multipurpose fastener can be used to assemble an electronic device having a housing, a first printed circuit board (PCB), and a second PCB. The multipurpose fastener includes a sleeve portion. The sleeve portion includes at least the following: first region including a first conductive pathway, a second region including a second conductive pathway, and a third region electrically isolating the first conductive pathway from the second conductive pathway. When the sleeve portion is disposed between the first PCB and the second PCB, the sleeve portion provides a fixed distance between the first PCB and the second PCB.

In yet another embodiment, an electronic device is disclosed. The electronic device includes at least the following: an electronic device housing; a first printed circuit board (PCB), a second PCB oriented substantially parallel to the first PCB, and a multipurpose fastener. The multipurpose fastener includes at least the following: a body portion having a first end secured to the housing, and a sleeve portion configured to establish a pre-defined distance between the first PCB and the second PCB. The multipurpose fastener is configured to provide at least two discrete electrically conductive pathways between the first PCB and the second PCB.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The described embodiments may be better understood by reference to the following description and the accompanying drawings. Additionally, advantages of the described embodiments may be better understood by reference to the following description and accompanying drawings. These drawings do not limit any changes in form and detail that may be made to the described embodiments. Any such changes do not depart from the spirit and scope of the described embodiments.

FIG. 1 shows a cross-sectional side view of a pair of printed circuit boards electrically and mechanically coupled together within a housing by a multipurpose fastener.

FIG. 2A-2B show embodiments similar to the one shown in FIG. 1 with the addition of a sleeve portion.

FIG. 3A shows a perspective view of a main logic board and power supply board coupled together by a fastener.

FIG. 3B shows a perspective view of another embodiment of a main logic board and power supply board coupled together by a fastener.

FIGS. 4A-4B show a partial cross-sectional perspective view of an electronic device.

FIGS. 5A-5B show a single piece body portion used in conjunction with a split sleeve portion.

FIGS. 5C-5D show another embodiment of a single piece body portion used in conjunction with a split sleeve portion.

FIGS. 6A-6B show another fastener configuration in which a heat stake is used to mechanically couple two printed circuit boards within a housing.

FIG. 7A shows a top down cross-sectional view of a multipurpose fastener.

FIG. 7B shows another embodiment in which a sleeve portion has a number of conductive elements running through it.

FIG. 7C shows another embodiment in which a notch is disposed on an exterior surface of the sleeve portion and configured to align with a complementary alignment feature.

FIG. 8 shows a flow chart depicting process 800 for installing a multipurpose fastener.

FIG. 9 shows a flow chart depicting process 900 for installing a multipurpose fastener.

### DETAILED DESCRIPTION OF SELECTED EMBODIMENTS

Representative applications of methods and apparatus, according to the present application, are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings which form a part of the description and in which are shown, by way of illustration, specific embodiments in accordance with the described embodiments. Although these embodiments are described in sufficient detail to enable one skilled in the art to practice the described embodiments, it is understood that these examples are not limiting, such that other embodiments may be used, and changes may be made, without departing from the spirit and scope of the described embodiments.

Conventional assembly techniques used in the manufacture of electronic devices generally rely upon a connector formed of a conductive material (such as solder, copper, etc.) to electrically couple internal electronic components. For example, various electronic components are mounted to a substrate and electrically connected to conductive trace connections to form what is referred to as a printed circuit board, or PCB. In order for the electronic device to operate in a prescribed manner, it may be necessary for one PCB to be electrically and mechanically connected to another PCB. For example, a first PCB in the form of a main logic board, or MLB, having a central processing unit, or CPU, can be electrically coupled to a second PCB in the form of a power supply board (PSB) using a single purpose electrical connector (referred to as a board-to-board connector). The board-to-board connector is used to provide an electrical connection between the PSB and MLB over which power (from the PSB to the MLB) and control signals (from the MLB to the PSB) can pass. Therefore, in the context of this discussion, the single purpose of the electrical connector refers to providing the electrical connection over which the various signals pass. A single purpose mechanical connector, such as a screw, can be used to mechanically secure the MLB and PSB to each other and/or to a support structure, such as a device housing. In this way, the device housing can provide structural support for the MLB and PSB.

However, when at least a portion of the device housing is electrically conductive, the device housing can be used as a chassis ground using yet another electrical connector to form a conductive path to the device housing. Therefore, assembly of the electronic device using an assembly process that relies upon single purpose connectors generally requires multiple instances of individual electrical and mechanical connectors. Accordingly, the overall part count and the complexity of the assembly process are increased resulting in a more costly and time consuming manufacturing experience. In addition to complicating the assembly process, the use of single purpose fasteners/connectors can take up valuable internal space that could otherwise be used for additional electronic components.

Therefore, an efficient fastener/connector system is described for use in assembly of an electronic device. The efficient fastener/connector system has the capability of both mechanically fastening and electrically connecting selected components disposed within a device housing. In one embodiment, the efficient fastener/connector system can take the form of a multipurpose fastener. The multipurpose fastener can include features that can be used for both electrically connecting and mechanically securing components of the electronic device. For example, a single multipurpose fastener can be used to mechanically and electrically couple a first PCB to a second PCB as well as to a device housing. Moreover, the same multipurpose fastener can also be used to provide a path to a conductive portion of the device housing to form a chassis ground. In this way, a single multipurpose fastener can be used to replace at least three conventional single purpose fasteners. Accordingly, the multipurpose fastener can greatly reduce part count, assembly complexity, and increase available space that can be used for additional electronic components.

The multipurpose fastener can take many forms. In one embodiment, the multipurpose fastener can include a body portion having features that cooperate to form electrical and mechanical connections. For example, the body portion can include a conductive element configured to form a conductive path between various components. The body portion can also include a mechanical element configured for fastening and securing selected ones of the components. The mechanical element can also provide structural aspects that can be used for placement of selected components within the device housing. For example, the body portion can include a mechanical fastening element in the form of a screw, or other such fastener, that can be used to mechanically secure a first PCB to a second PCB as well as to a support structure such the device housing. The mechanical fastening element can also include a structural element such as a sleeve. The sleeve can be secured to the first and second PCB and be used to position the first PCB with respect to the second PCB as well as with respect to other components or structural members. In some embodiments, the sleeve can include aspects that can be used to form electrically conductive paths. For example, the sleeve can include a first region having conductive material configured to provide a first conductive path. The sleeve can also include a second region having conductive material configured to provide a second conductive path. The first and second regions can be separated by a third region formed of electrically insulating material. In this way, the sleeve can provide structural support as well as any number of electrically conductive paths.

In one specific embodiment, a multipurpose fastener for securing at least the first and second PCBs to a housing of an electronic device can include: a housing insert, a body portion, a sleeve portion, and a fastening portion. The housing insert can be used to secure the body portion to the housing. As such, the housing insert can include a retention feature for coupling to the body portion. In some embodiments, the housing insert can be formed of electrically conductive material capable of providing a chassis ground in those situations where the chassis ground is not available (such as housing formed of non-conductive material such as plastic or ceramic). In this way, the housing insert can act as both retainer and a chassis ground.

An advantage of the multipurpose fastener is that the structure and the composition of the multipurpose fastener can take on many forms as may be required for a particular application. For example, in one embodiment, the multipurpose fastener can include a housing insert embedded in the housing during an injection molding process. In other cases, the insert can have a threaded portion such that the insert can engage with a corresponding threaded portion of the housing. Accordingly, the body portion can have a threaded first end coupled to the retention feature of the housing insert. In yet other cases, the housing insert can be press-fit, heat-staked, glued, or bonded to the housing. The body portion can have an electrical coupling feature operable to electrically couple electrical components secured to the body portion. For example, the electrical coupling feature can be used to electrically couple a first PCB to a second PCB. In this arrangement, the first PCB can be configured with an opening through which the body portion can pass. In some embodiments, the opening can take the form of a hole formed in the substrate of the first PCB. In other embodiments, the opening can take the form of a notch such that the first PCB only partially surrounds the body portion.

In another embodiment, the body portion can include a conductive sleeve portion that can be placed, in whole or in part, around the body portion. The conductive sleeve portion and body portion of the fastener can be separated by an insulation layer disposed between the conductive sleeve portion and the body portion. In some embodiments, the insulation layer can be disposed on an outer surface of the body portion. In other embodiments, the insulation layer can be disposed on an inside surface of the conductive sleeve portion. The conductive sleeve portion can be placed in such a way that the conductive sleeve portion can come in contact with selected conductive traces. In this way, conductive traces on the first and the second PCB can be electrically coupled together using the conductive sleeve portion.

In another embodiment, a multipurpose fastener can include at least a body portion and a sleeve portion. In this embodiment, the body portion can be coupled directly to the housing of an electronic device. In some embodiments, the fastening portion can be overmolded directly into the housing while, in other embodiments, a first end of the fastening portion can be threaded into the housing. In one specific embodiment, the first end of the fastening portion can be a self-tapping screw configured to engage an inner surface of the housing such that the first end of the body portion embeds itself into the housing. In other embodiments, the threaded portion of the body portion can engage threads associated with a pre-drilled hole to secure the fastening portion to the housing. In various other embodiments the body portion can be adhesively coupled, bonded, soldered, or press-fit into a portion of the housing.

Once the fastening portion is secured to the housing, a first PCB can be secured to the fastening portion. The first PCB can be secured to the fastening portion by an opening in the first PCB. The first PCB can be arranged on a flange feature of the fastening portion disposed proximate to the first end of the fastening portion. The flange feature can electrically couple the fastening portion to electrical traces disposed on a lower surface of the first PCB. A lower surface of the sleeve portion can be in direct contact with an upper surface of the first PCB and installed about the fastening portion of the fastener. In this embodiment, the sleeve portion has at least two separate conductive paths disposed therein. The conductive paths can be configured to electrically couple the first PCB to a second PCB in direct contact with an upper surface of the sleeve portion. The fastening portion of the fastener can also extend through an opening in the second PCB and a malleable head feature of the fastening portion can be reshaped after the second PCB is assembled below the head feature. In this way, the second PCB can be disposed between an upper surface of the sleeve portion and the reshaped malleable head feature of the fastening portion. In some embodiments, the reshaping of the head portion can electrically couple the fastening portion to an upper surface of the second PCB, thereby providing another electrically conductive pathway between the two PCBs.

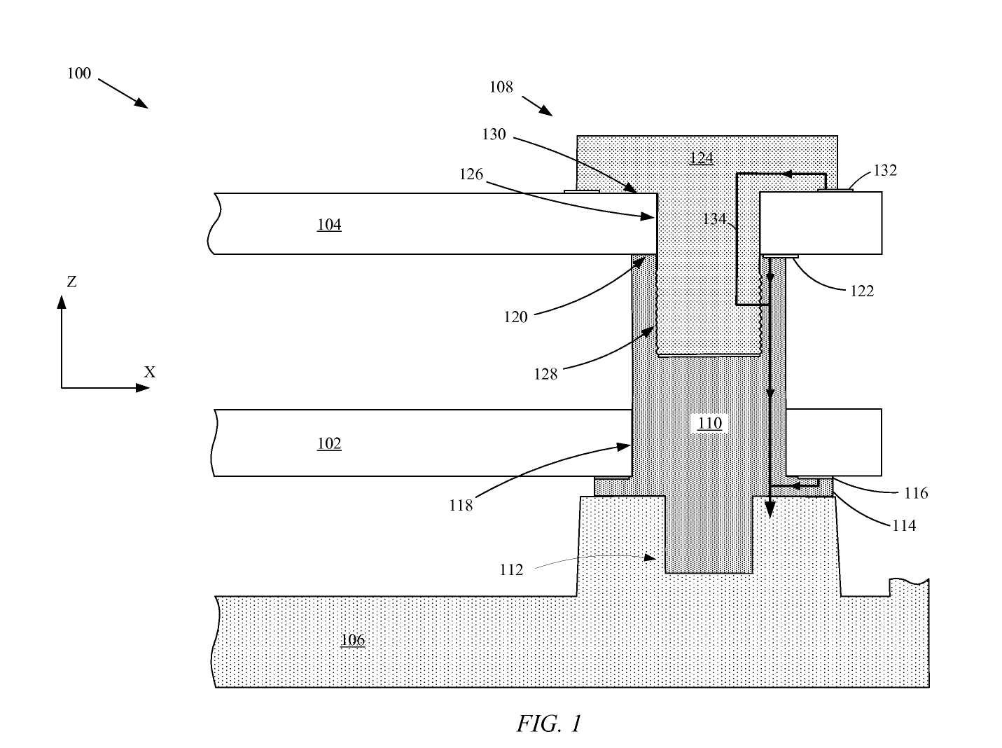

These and other embodiments are discussed below with reference to FIGS. 1-9; however, those skilled in the art will readily appreciate that the detailed description given herein with respect to these figures is for explanatory purposes only and should not be construed as limiting.

FIG. 1 shows a cross-sectional side view 100 of first PCB 102 and second PCB 104 in accordance with the described embodiments. As shown, PCB 102 and PCB 104 can be electrically and mechanically coupled together and to housing 106 using multipurpose fastener 108. PCB 102 and PCB 104 can take many forms. For example, PCB 102 can take the form of a main logic board (MLB) 102 whereas PCB 104 can take the form of a power supply board (PSB) 104. In the depicted embodiment, multipurpose fastener 108 can mechanically connect MLB 102 with respect to PSB 104. End 112 of body portion 110 is secured to housing 106. End 112 of body portion 110 can be coupled to housing 106 in a variety of different ways, including at least the following: threading, over molding, adhesively coupling, bonding, soldering, or press-fitting. Body portion 110 also includes a flange portion 114 configured to both mechanically support a lower surface of MLB 102 and electrically couple body portion 110 to at least one electrical trace 116 arranged on a lower surface of MLB 102. In this way, an electrical component electrical coupled to electrical trace 116 can also be in electrical contact with body portion 110. When disposed through opening 116 in MLB 102, body portion 110 can effectively constrain MLB 102 in the X-Y plane and in the Z direction.

Fastener 108 can also be mechanically and electrically coupled to PSB 104. Second end 120 of body portion 110 can mechanically support a lower surface of PSB 104. Second end 120 can also be electrically coupled to electrically conductive trace 122 disposed on a lower surface of PSB 104. In this way, body portion 110 can be in electrical communication with any electrical components electrically coupled to electrically conductive trace 122. In this depiction, body portion 110 is shown mechanically coupled to fastening portion 124 of fastener 108 through opening 126 in PSB 104. The mechanical coupling between fastening portion 124 and body portion 110 can be at threaded interface 128. When threading on both body portion 110 and fastening portion 124 is conductive, the body portion and fastening portion 124 can be electrically coupled, thereby causing any components in electrical communication with body portion 110 to also be in electrical communication with fastening portion 124. Opening 126 can restrain PSB 104 in the X-Y plane, while second end 120 of body portion 110, in cooperation with bottom surface 130 of fastening portion 124, can secure PSB 104 in the Z-axis. In this way, fastening portion 124 cooperates with body portion 110 to mechanically constrain PSB 104 in each of axes X, Y and Z. Fastening portion 124 can also be in contact with electrically conductive trace 132. This particular configuration can then allow each of electrically conductive traces 116, 122, and 132 to each be in electrical contact across electrically conductive pathway 134. It should be noted that, in other embodiments, body portion and fastening portion 124 can be a single integrally formed piece.

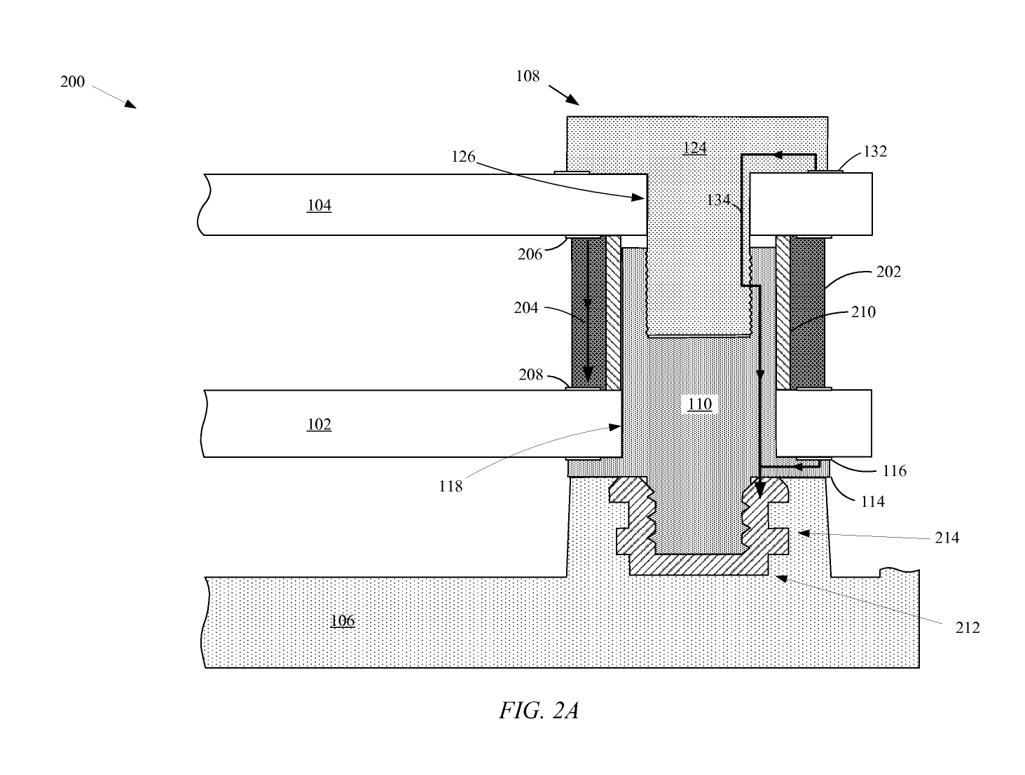

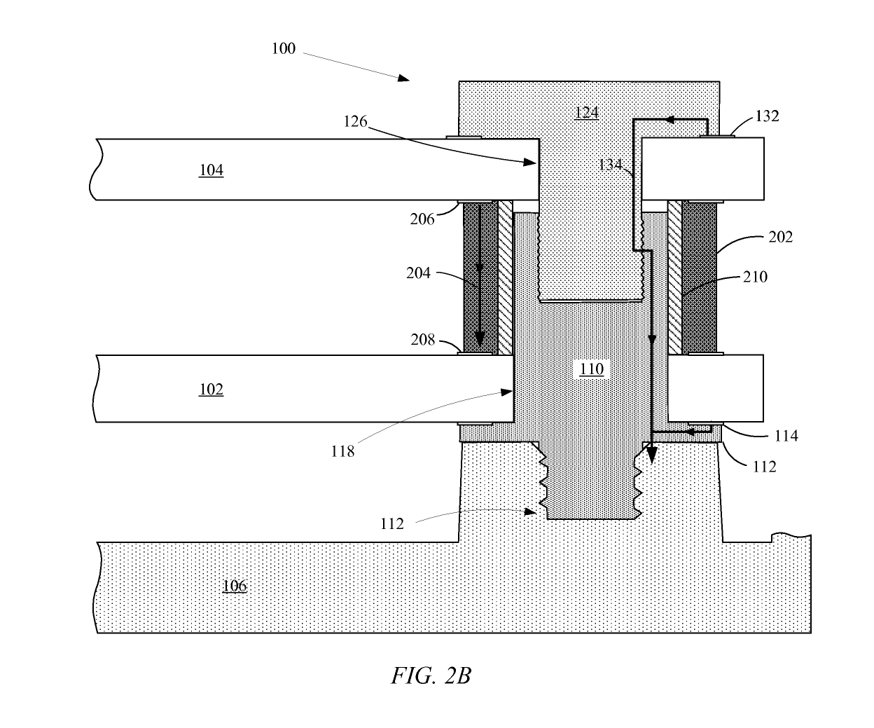

FIGS. 2A-2B show cross-sectional side views of other embodiments of a multipurpose fastener. FIG. 2A depicts a multipurpose fastener, including both a sleeve portion and a housing insert. Sleeve portion 202 of fastener 108 can be configured to at least partially surround body portion 110 of fastener 108. In terms of mechanical constraints, sleeve portion 202 can be configured to set a specific distance between MLB 102 and PSB 104. Sleeve portion 202 can also provide a restraint against which fastening portion 124 can be tightened against body portion 110. In terms of electrical connectivity, sleeve portion 202 can include embedded conductive elements or, in some embodiments, sleeve portion 202 can be constructed from a single conductive material. In either case, sleeve portion 202 can provide at least one conductive pathway between MLB 102 and PSB 104. Depicted conductive pathway 204 couples electrically conductive traces 206 and 208. In some embodiments, one of body portion 110 and sleeve portion 202 can include a layer of insulation preventing an electrical short between body portion 110 and sleeve portion 202. For example, body portion 110 can be configured with an insulating layer wrapped about it, or, as depicted, sleeve portion 202 can include insulation layer 210 preventing contact between conductive elements of body portion 110 and sleeve portion 202. In some embodiments, insulation layer 210 can be a layer of paint that provides sufficient insulation between the sleeve portion and the body portion while, in other embodiments, insulation layer 210 can be a more substantial layer of, for example, rubber, plastic or any other dielectric material. In still other embodiments, insulation layer 210 can be compressible and configured to provide a tight fit between sleeve 202 and body portion 110. In this way, sleeve portion can be arranged in a consistent position with respect to body portion 110.

FIG. 2A also depicts housing insert 212. In embodiments where housing 106 is an injection molded housing, housing insert 212 can be overmolded within housing 106. Outer flanges 214 of housing insert 214 can help to secure housing insert within housing 106 in an overmolded configuration. In other embodiments, insert 212 can have its own set of threads allowing it to be screwed directly into housing 106. In yet other embodiments, housing insert can be soldered, bonded or adhesively coupled with housing 106. Insert 212 can also have internal threading features configured to receive body portion 110 of multipurpose fastener 108. Body portion 110 can be coupled to housing insert 212 by threading it into the internal threading features of housing insert 212.

FIG. 2B shows an alternative embodiment in which end 112 of body portion 110 is coupled directly to housing 106. This direct coupling can be accomplished in a number of ways, including at least the following ways: body portion 110 can be threaded into a set of formed threads of housing 106; body portion 110 can be a self-tapping screw configured to thread itself into housing 106; body portion 110 can be adhesively coupled to housing 106; body portion 110 can be soldered to housing 106; or body portion 110 can be heat-staked into housing 106. In this embodiment, it should be noted that grounding path 134 can terminate with body portion 110 or, as depicted, can continue into housing 106 when housing 106 is a conductive housing. Alternatively, grounding path 134 can continue through another conductive grounding plane when the conductive grounding plane is arranged within housing 106 to contact body portion 110.

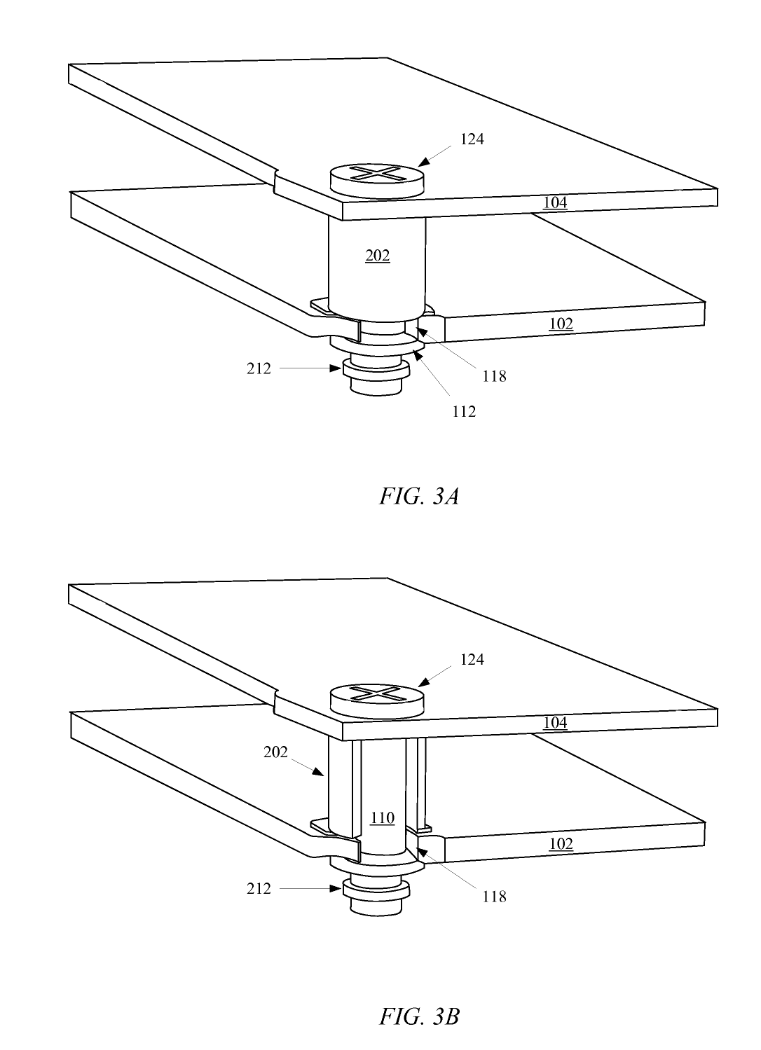

FIG. 3A shows a perspective view of a main logic board (MLB) and power supply board (PSB) coupled together. In this view, the housing portion has been removed to clearly show a configuration of both MLB 102 and PSB 104. In this particular embodiment, opening 118 of MLB 102 is actually embodied as notched opening 118. Notched opening 118 can make insertion of MLB 102 about body portion 110 a faster process than a configuration in which the opening is a hole that would be aligned with body portion 110 during assembly. Such a notched opening configuration can also be desirable when the multipurpose fastener is arranged near an inner surface of the housing. Notched opening 118 can allow body portion 110 to be positioned more closely to an inner surface of the housing, thereby leaving more central board space for components and signal routing. It should be noted that, while housing insert 212 is shown as a substantially cylindrical insert, an enlarged metallic insert is also possible in embodiments where housing insert 212 can act as a chassis ground for an associated electronic device, the enlarged metallic housing insert thereby providing improved grounding for the electronic device. FIG. 3B shows an alternative embodiment in which sleeve portion 202 only partially surrounds body portion 110 of the fastener. Such a configuration can reduce a footprint of the multipurpose fastener with respect to MLB 102 and power supply board 104. In some configurations, a reduced footprint sleeve portion can also ease an installation process of the multipurpose fastener as it can be slipped around body portion 110 of the multipurpose fastener.

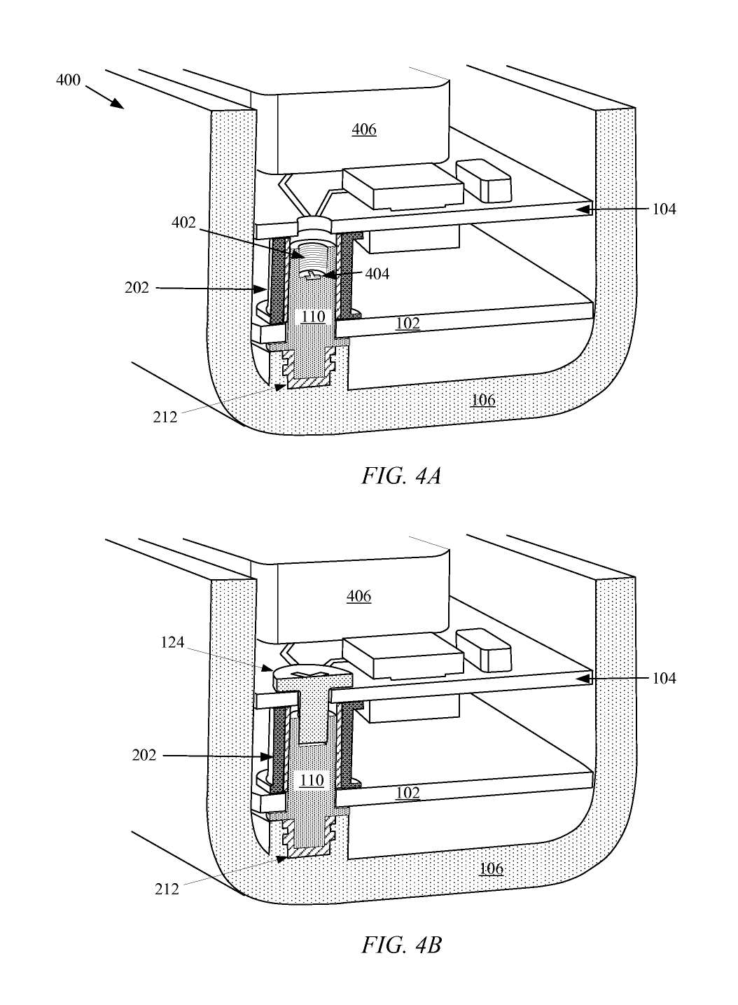

FIGS. 4A-4B show partial cross-sectional perspective views of an electronic device 400. Electronic device 400 can be configured with a main logic board (MLB) 102 and power supply board (PSB) 104 that are arranged within housing 106, MLB 102 and PSB 104 being disposed substantially parallel to one another. In FIG. 4A, a cross section of body portion 110 is visible. In this view, internal threading 402 of body portion 110 is visible as well as driving feature 404. Internal threading 402 can be configured to receive fastening portion 124, while driving feature 404 can be provided to allow body portion 110 to be rotated into housing insert 212. FIG. 4B shows fastening portion 124 threaded into internal threading 402 of body portion 110. In some embodiments, body portion 110 can be the only secure mechanical constraint on the two boards. In one particular embodiment, MLB 102 can rest on a shelf integrally formed in housing 106 such that both ends of MLB 102 receive support. Power supply board 104 can have its own corresponding integrally formed shelf. In this way, the two boards can be mechanically constrained by a single fastener, thereby freeing up extra board space and housing volume for other components, such as, for example, power supply component 406, and/or other components requiring relatively large volumetric space in a relatively diminutive housing.

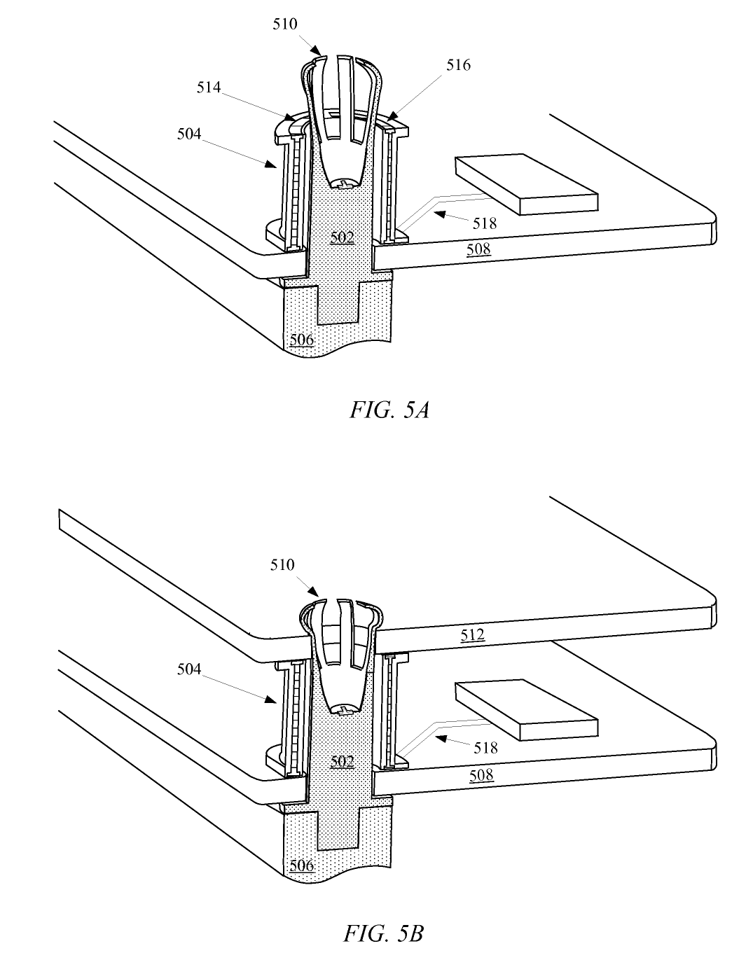

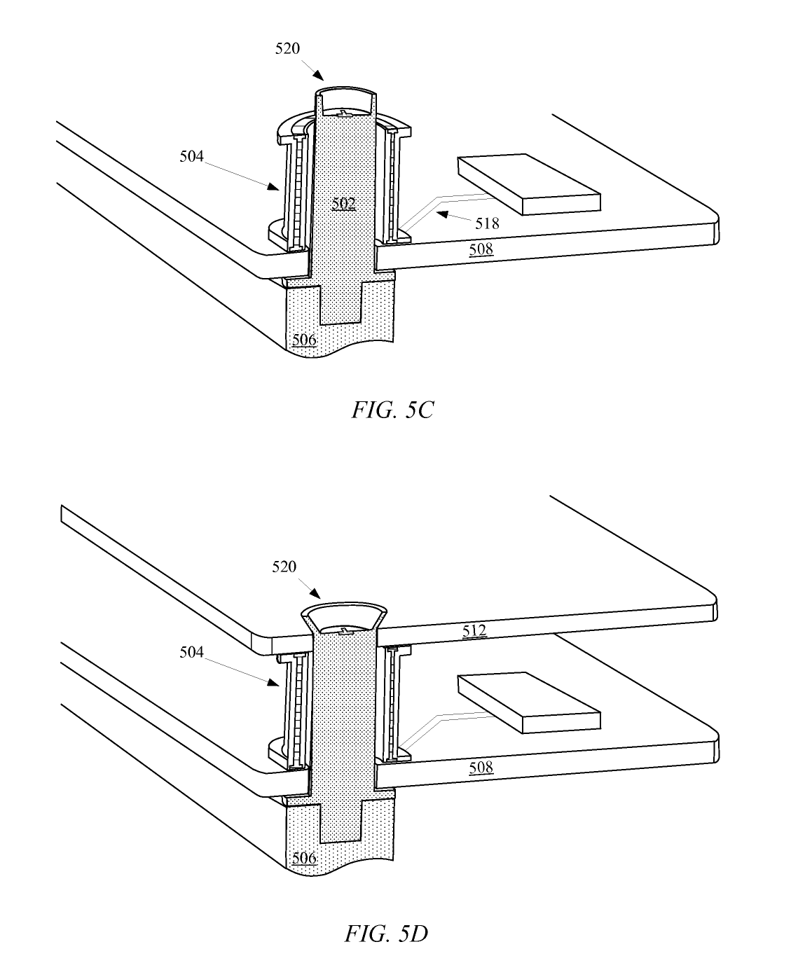

FIGS. 5A-5B show a single piece body portion 502 with a split sleeve portion 504. In FIG. 5A, body portion 502 can be glued into housing 506 or, in other embodiments, any number of other previously mentioned methods can be used to couple body portion 502 to housing 506. It should be noted that body portion 502 can also be soldered or heat-staked into housing 506. Once body portion 502 is secured within housing 506 main logic board (MLB), 508 can be installed. Subsequently, split sleeve portion 504 can be installed about body portion 502. Fastening portion 502 can include prongs 510 which can temporarily bend inwards as split sleeve portion 504 is placed over body portion 502 during installation. In FIG. 5B, power supply board 412 can be inserted over prongs 510 which can be temporarily bent inward to pass through an opening in power supply board 512. Following positioning of power supply board 512 within housing 506, prongs 510 can be reshaped or swaged in a swaging process. Swaged prongs 510 of fastening portion 502 are then configured to secure power supply board 512 between swaged prongs 510 and split sleeve portion 504.

Split sleeve portion 504 can have at least two distinct regions having conductive elements 514 and 516 disposed within a third region of insulation that is operable to both enclose conductive elements 514 and 516 and to electrically isolate them from each other. Conductive elements 514 and 516 can take the form of a curved I Beam, as depicted, such that they provide a substantial amount of structural support for split sleeve portion 504. Conductive elements 514 and 516 can show through the insulation region at least along a top and bottom surface of split sleeve portion 504 so that conductive elements 514 and 516 can be electrically coupled to conductive traces, such as trace 518, arranged on MLB 508. A split configuration of conductive elements in split sleeve portion 504 allows power to be passed through conductive element 514 and a grounding path to be established through conductive element 516. A number of distinct electrical traces can be coupled to each of conductive elements 514 and 516 allowing power delivery and grounding to a number of different components within an associated electronic device. In embodiments where body portion 502 is made of a conductive material, body portion 502 can act as an additional grounding path, power transfer conduit, or signal pathway in addition to the paths provided by conductive element 514 and 516. FIGS. 5C and 5D illustrate an alternative fastening portion embodiment having malleable lip 520. As illustrated in FIGS. 5C and 5D, malleable lip 520 can be reshaped after the installation of power supply board 512 such that power supply board 512 is secured between malleable lip 520 and a top surface of split sleeve portion 504.

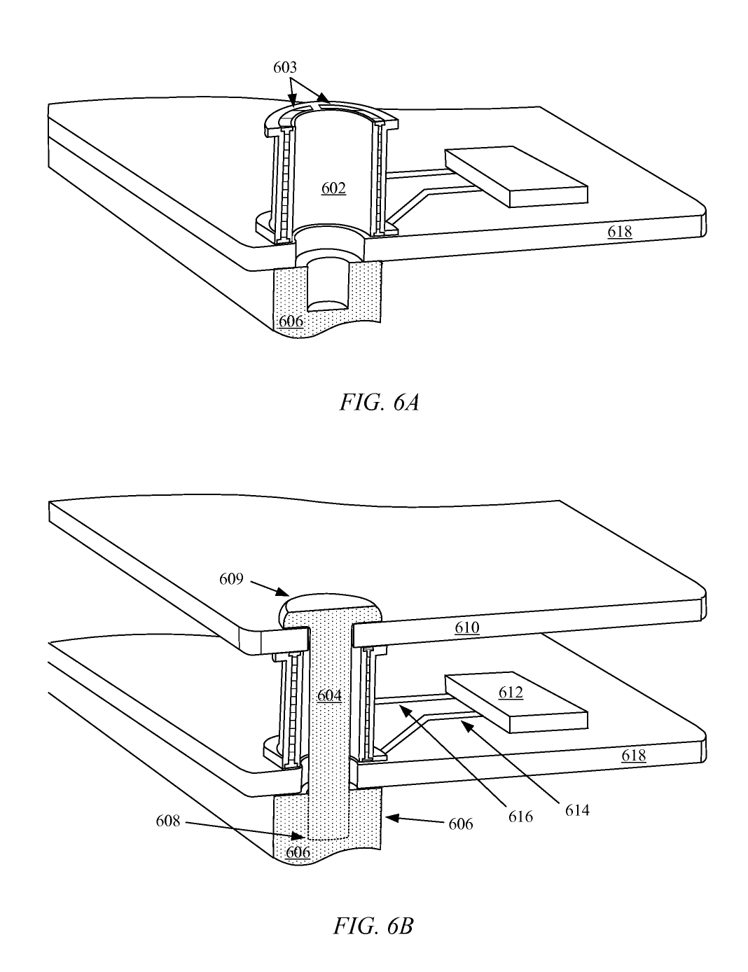

FIGS. 6A-6B show another fastener configuration in which a heat-stake is used to mechanically couple two printed circuit boards within a housing. In FIG. 6A, split sleeve portion 602 is depicted. In some embodiments, split sleeve portion 602 can be made of a compressible material. Compression of a compressible sleeve portion 602 can increase conductivity of the material, such as, for example, in an embodiment where conductive elements 603 are formed from a polymer doped with conductive particles. Compression of sleeve portion 602 can also more reliably keep sleeve portion 602 firmly in place after installation as friction between sleeve portion 602 and the two printed circuit boards can be increased by the compression. Overall compression of the sleeve can result in a more robust design allowing the fastener to stay in tension regardless of environmental conditions, such as, for example, temperature variations and product drops. In FIG. 6B, body portion 604 can be a nonconductive stake that is heat staked into housing 606. Body portion 604 can be made of a plastic material substantially similar to a material of housing 606. By heating body portion 604 and inserting it through the two printed circuit boards, end 608 of body portion 604 can adhere to housing 606, thereby quickly coupling PCB 610 and 618 to housing 604. Dotted portion 608 of body portion 604 depicts where body portion 604 has melted to be joined to the opening in housing 606. It should be noted that, in some embodiments, body portion 604 is already part of housing 606 prior to installation of the other depicted components. In one specific embodiment, head feature 609 of body portion 604 can be formed by heating a top end of body portion 604 such that head feature 609 is formed, head feature 609 being operable to mechanically constrain a top surface of power supply board 610 to split sleeve portion 602.

Since split sleeve portion 602 is configured as described above to act as both a grounding and power conduit, power and grounding can still be accomplished with this embodiment of the multipurpose fastener. For example, power supply board 610 can include a grounding pathway allowing electrical component 612 to be grounded through electrical trace 614, which can then be routed through conductive elements 603 of split sleeve portion 602 and then to a ground plane associated with power supply board 610. Likewise, electrical component 612 can be electrically coupled to a second electrical trace 616, which can then be electrically coupled to a conductive element 603 of split sleeve portion 602. In this way, electrical component 612 can be both grounded and powered through a multipurpose fastener that includes only two parts. It should be noted that while body portion 604 is not shown in direct contact with sleeve portion 602, such a configuration can be desirable, as contact between body portion 604 and sleeve portion 602 can help to ensure proper radial alignment of sleeve portion 602 with respect to PCB 610 and PCB 618. It should be noted that while only one side of each of the boards is electrically coupled, the remaining sides can also benefit from the electrical coupling by way of more traditional vias disposed through each of the boards.

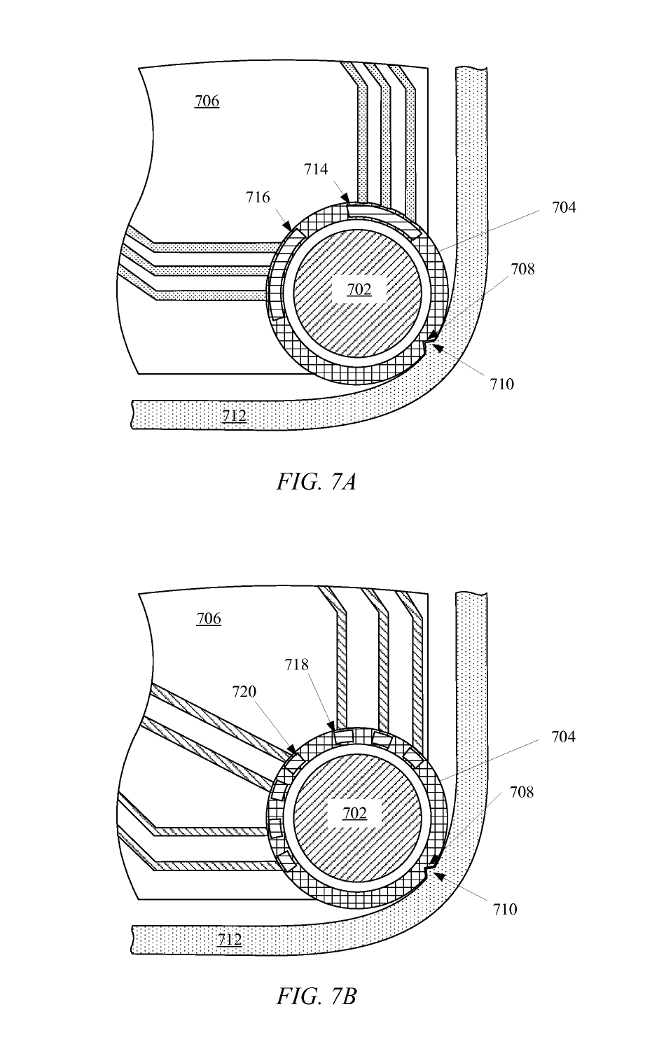

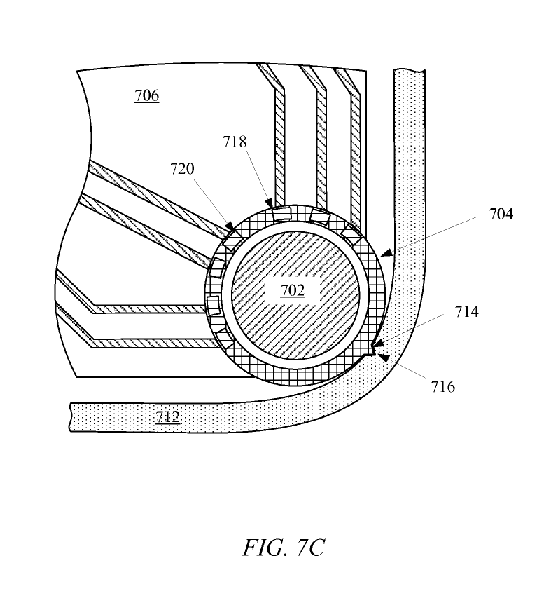

FIG. 7A show a top down cross-sectional view of a multipurpose fastener. The multipurpose fastener can include a conductive or non-conductive body portion 702 providing at least mechanical constraints between main logic board 706, a power supply board (not shown) and sleeve portion 704. The multipurpose fastener functions to establish a minimum distance or interval between the boards and to act as a conduit for power and grounding purposes. In this particular embodiment, sleeve portion 704 includes notch 708 that is configured to mate with alignment feature 710 which can be integrally formed in housing 712. In this way, sleeve portion 704 and housing 712 can interact in a way that aligns conductive elements 714 and 716 with respective traces. Such a configuration can increase assembly reliability as alignment feature 710 can prevent sleeve portion 704 from being radially misaligned.

FIG. 7B shows another embodiment in which sleeve portion 704 has a large number of conductive elements running through it. Such a configuration can be desirable when, for example, different power voltages are passed between circuit boards. In this embodiment, power can be passed at 3.3V through conductive element 718, while power can also be passed at 5V through conductive element 720. Others of the depicted conductive elements can be used as grounding pathways, different electrical voltages, and even discrete signals in some embodiments. For example, in one embodiment, an integrated circuit on main logic board 702 can be used to shut down the power supply component on the power supply board. In this configuration, the integrated circuit can be electrically coupled to the power supply component through the depicted multipurpose fastener. It should be noted that this depicted configuration makes the rotational position of sleeve portion 704 even more important as a minor angular positioning error of sleeve portion 704 can result in a mismatch of connections or, in some cases, even a total lack of a connection. While notch 708 and alignment feature 710 depict one way to align sleeve portion 704 with housing 712, other ways are certainly possible. For example, sleeve portion 704 can have an asymmetric geometry such that it fits with respect to housing 712 in only a single orientation, thereby preventing incorrect installation. It should be noted that smaller conductive elements can reduce a structural resilience of sleeve portion 704; however, insulation surrounding the conductive elements can be made of durable and stiff materials such as, for example, hard plastic. FIG. 7C shows an alternative configuration in which notch 714 is disposed on an exterior surface of sleeve portion 704 and is configured to align with an alignment feature 716 disposed on an interior surface of housing 712. By aligning notch 714 with alignment feature 716 during assembly, a correct orientation of sleeve portion 704 with respect to electrical traces disposed on main logic board 706 can be achieved.

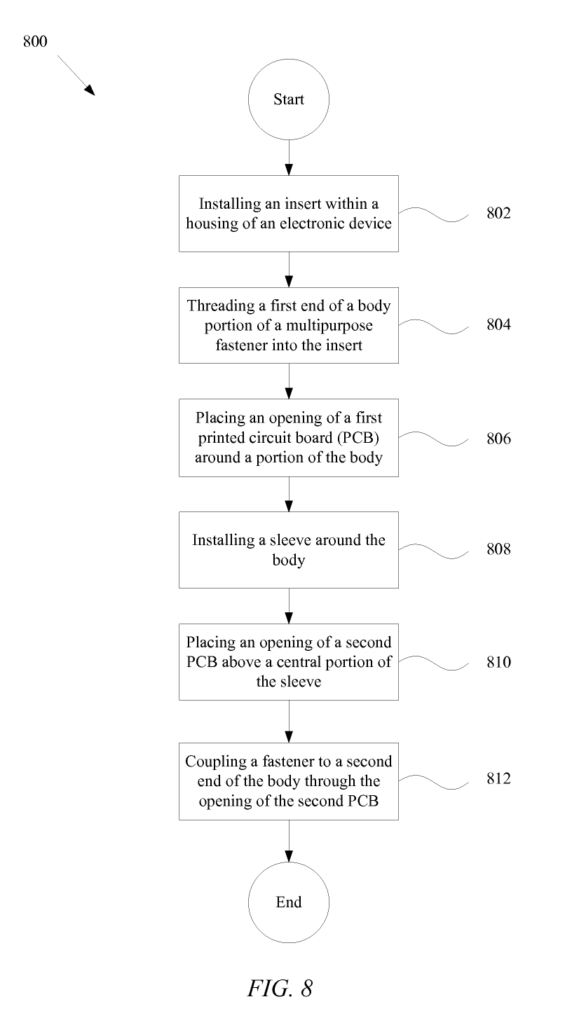

FIG. 8 shows a flow chart depicting process 800 for installing a multipurpose fastener. In a first step 802, an insert is installed within a housing of an electronic device. The insert can be a metallic insert having attachment features on both an inner and outer surface of the insert. Outer attachment features can be configured to hold the insert within the housing. In some embodiments, the outer attachment features can be flanges configured to hold the insert within the housing inside of which it has been overmolded. In another embodiment, the outer attachment features can be fastener threads configured to be threaded into the housing. Inner attachment features are configured to hold a body portion of the fastener. In step 804, the body portion, having a size and shape in accordance with the inner attachment features of the insert, is threaded into the insert. In this way, a first end of the fastener can be securely fastened to the housing. It should be noted that, in some embodiments, the body portion can be adhesively coupled to the insert or in other embodiments directly to the housing. At step 806, a first printed circuit board (PCB) is arranged about the body portion. The first PCB can have an opening that accommodates the body portion. The opening can be circular or can alternatively be a notched portion of the first PCB. At step 808, a sleeve portion is installed about the body portion. The sleeve portion is at least partially conductive and can include a layer of insulation that prevents contact between conductive portions of the body portion and the sleeve portion. The insulation can be disposed along an inner surface of the sleeve portion and/or on an exterior surface of the body portion. In some embodiments, the insulation can create a precise fit between the sleeve portion and the body portion such that any radial misalignment of the sleeve portion can be avoided. In still other embodiments, an alignment feature can be disposed on an exterior surface of the sleeve portion. The alignment feature can cooperate with the housing to ensure rotational alignment of the sleeve portion with respect to the first PCB. The alignment feature can be an asymmetric geometry of an exterior of the sleeve portion, the asymmetric shape requiring a specific orientation for the sleeve to be positioned about the body portion. In another variation, the alignment feature can be a single protrusion configured to align with a notch integrally formed in the housing.

At step 810, a lower surface of a second PCB can be put in direct contact with the sleeve portion. The conductive nature of the sleeve portion allows the sleeve portion to electrically couple the first and second PCBs together. The sleeve portion can include multiple conductive elements providing separate electrically conductive paths through the sleeve portion. In one embodiment, power of varying voltages can be passed through the different conductive paths. An electrically conductive grounding path is also possible. At step 812, a fastening portion is inserted through an opening in the second PCB and into a retention feature of the body portion. Once the fastening portion is secured within the retention feature of the body portion, a head portion of the fastener is put in direct contact with a surface portion of the second PCB. In this way, that surface portion of the second PCB can be electrically coupled through the fastening portion and the body portion to the housing. The portion of the housing to which the body attaches can be coupled to a chassis ground, thereby efficiently coupling both the first and second PCB to the chassis ground.

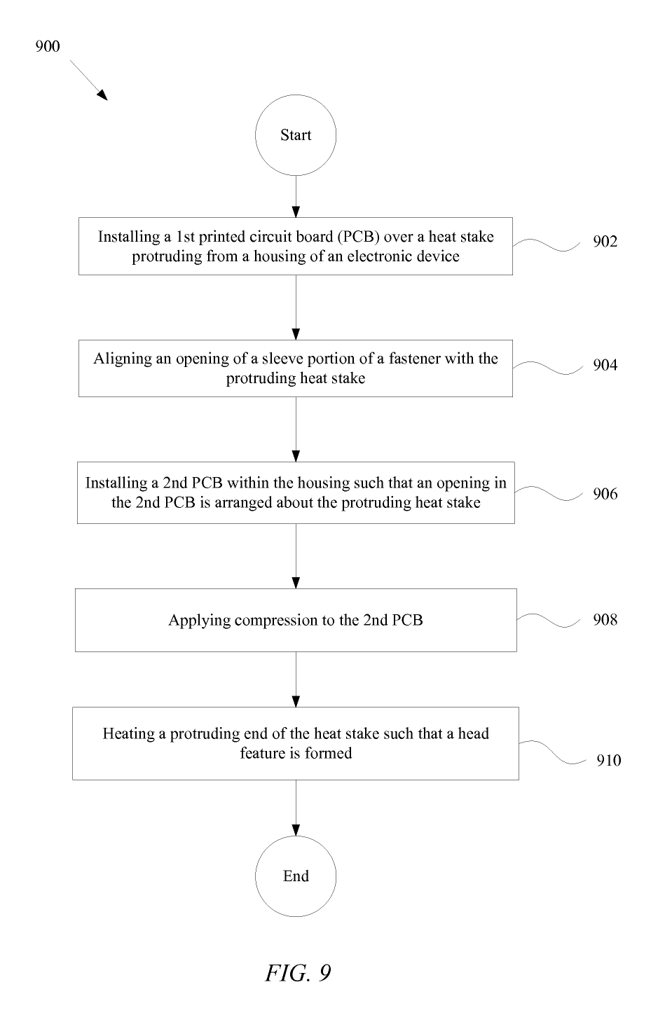

FIG. 9 shows a flow chart depicting process 900 for installing a multipurpose fastener. In a first step 902, a first printed circuit board (PCB) is installed within a housing of an electronic device. The first PCB is installed such that an opening in the first PCB is disposed about a portion of a heat stake protruding from the housing of the electronic device. At step 904, a conductive sleeve portion of the fastener is aligned with the opening in the first PCB by installing it about the protruding heat stake. At step 906, a second PCB is installed within the housing such that an opening in the second PCB is disposed about the protruding heat stake. Once the second PCB is installed, the sleeve portion can electrically couple the first and second PCB together. In some embodiments, the sleeve portion can be configured with a number of conductive elements arranged to create a number of electrically conductive pathways between the first and second PCBs. In one embodiment, a first electrically conductive pathway disposed within the sleeve portion can provide a power conduit between the two PCBs, and a second electrically conductive pathway disposed within the sleeve portion can provide a grounding path for components arranged on either the first PCB or the second PCB. At step 908, the second PCB can be compressed against the sleeve portion. In this way, reliability of electrical connections between the two circuit boards can be improved as well as an actual mechanical positioning of the sleeve portion with respect to the first and second PCB. At step 910, a protruding end of the stake extending above the second PCB can be heated and reformed such that a head feature is formed that, can after cooling, be configured to maintain the compressed second circuit board in position, thereby maintaining compression within the multipurpose fastener.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A multipurpose fastener used to assemble an electronic device comprising a housing and at least a first printed circuit board (PCB) comprising electrically conductive traces, and a plurality of electronic components electrically interconnected by way of the electrically conductive traces, the multipurpose fastener comprising:
a body portion, comprising:
a mechanical securing feature configured to mechanically secure the first PCB, and
an electrical connection feature configured to electrically connect to at least one of the electrically conductive traces of the first PCB.

2. The multipurpose fastener as recited in claim 1, further comprising:
a sleeve portion disposed at least partially around the body portion and configured to establish a fixed distance between the first PCB and a second PCB.

3. The multipurpose fastener as recited in claim 2, wherein the sleeve portion comprises:
a first region comprising a conductive element providing a first conductive pathway between the first PCB and the second PCB.

4. The multipurpose fastener as recited in claim 3, wherein the sleeve portion further comprises:
a second region comprising a conductive element providing a second conductive pathway between the first PCB and the second PCB; and
a third non-conductive region configured to mechanically couple the first and second regions together and to electrically isolate the first conductive pathway from the second conductive pathway.

5. The multipurpose fastener as recited in claim 4, wherein the first and second electrically conductive pathways provide a grounding pathway and a power conduit respectively between the first and second PCBs.

6. The multipurpose fastener as recited in claim 4, wherein the sleeve portion is compressible.

7. The multipurpose fastener as recited in claim 4, wherein the sleeve portion further comprises a notch disposed on an exterior surface of the sleeve portion, the notch configured to interact with an alignment feature disposed on an interior surface of the housing such that the alignment feature facilitates proper alignment of at least the first and second conductive pathways with respect to a plurality of electrically conductive traces disposed on the first PCB and the second PCB.

8. The multipurpose fastener as recited in claim 2, wherein the body portion further comprises a first end secured to and in electrical contact with the housing.

9. The multipurpose fastener as recited in claim 8, wherein a flange of the body portion is electrically coupled to a bottom surface of the first PCB and a head feature of the body portion is electrically coupled to a top surface of the second PCB.

10. A multipurpose fastener used to assemble an electronic device comprising a housing, a first printed circuit board (PCB) and a second PCB, the multipurpose fastener comprising:
a sleeve portion, comprising:
a first region comprising a first conductive pathway,
a second region comprising a second conductive pathway, and
a third region electrically isolating the first conductive pathway from the second conductive pathway,
wherein when the sleeve portion is disposed between the first PCB and the second PCB the sleeve portion provides a fixed distance between the first PCB and the second PCB.

11. The multipurpose fastener as recited in claim 10, wherein the first conductive pathway is electrically coupled to both a first electrically conductive trace disposed on a top surface of the first PCB, and a second electrically conductive trace disposed on a bottom surface of the second PCB.

12. The multipurpose fastener as recited in claim 11, further comprising:
a body portion configured to mechanically secure the first PCB and the second PCB to the housing of the electronic device, such that the first PCB is substantially parallel to the second PCB.

13. The multipurpose fastener as recited in claim 12, further comprising:
a fastening feature having a threaded first end, wherein the body portion comprises:
a first end secured to and in electrical contact with the housing, and a second end comprising a retention feature having a size and shape in accordance with the threaded first end of the fastening feature.

14. The multipurpose fastener as recited in claim 13, wherein a flange feature of the body portion is in electrical contact with a bottom surface of the first PCB and wherein the fastening feature is in electrical contact with a top surface of the second PCB.

15. The multipurpose fastener as recited in claim 12, wherein the sleeve portion at least partially surrounds the body portion and is electrically isolated from the body portion by a layer of insulation disposed between an inner surface of the sleeve portion and an outer surface of the body portion.

16. The multipurpose fastener as recited in claim 12, wherein the body portion is a stake integrally formed with the housing, and wherein the body portion includes a head portion formed by heating a protruding head of the stake after openings in the first PCB and the second PCB are disposed about the stake.

17. An electronic device, comprising:
an electronic device housing;
a first printed circuit board (PCB);
a second PCB oriented substantially parallel to the first PCB; and
a multipurpose fastener, comprising:
a body portion having a first end secured to the housing, and
a sleeve portion configured to establish a pre-defined distance between the first PCB and the second PCB,
wherein the multipurpose fastener is configured to provide at least two discrete electrically conductive pathways between the first PCB and the second PCB.

18. The electronic device as recited in claim 17, wherein an electrical signal can be passed over at least one of the discrete electrically conductive pathways, thereby putting a first electrical component on the first PCB in communication with a second electrical component on the second PCB.

19. The electronic device as recited in claim 18, wherein the body portion further comprises a malleable end opposite the first end, the malleable end configured to be reshaped in a swaging process, such that the reshaped malleable end fixes the second PCB to a top surface of the sleeve portion.

20. The electronic device as recited in claim 17, wherein the first end of the body portion is overmolded to the electronic device housing.

21. The electronic device as recited in claim 17, wherein the sleeve portion has an asymmetric geometry that in conjunction with an inner surface of the electronic device housing prevents radial misalignment of the sleeve portion with respect to a plurality of electrically conductive elements disposed on the first PCB and the second PCB.

22. The electronic device as recited in claim 17, wherein the body portion further comprises a malleable head feature configured to be reshaped once assembly of the first PCB and the second PCB within the housing is complete, the reshaped head feature of the body portion operative to constrain the first PCB and second PCB within the housing.
